(19) United States
(12) Patent Application Publication
(10) Pub. No.: US 2018/0236890 A1
(43) Pub. Date: Aug. 23, 2018

(54) System and Method of Battery Monitoring

(71) Applicant: FCA FIAT CHRYSLER AUTOMÓVEIS BRASIL LTDA., Betim (BR)

(72) Inventor: Luciano Tadeu Martins CYRNE, Padre Eustáquio (BR)

(73) Assignee: FCA FIAT CHRYSLER AUTOMOVEIS BRASIL LTDA.

(21) Appl. No.: 15/752,651

(22) PCT Filed: Aug. 17, 2016
(86) PCT No.: PCT/BR2016/050203

§ 371 Date: Feb. 14, 2018

(30) Foreign Application Priority Data
Aug. 19, 2015 (BR) BR 102015019906-6
Jul. 15, 2016 (BR) BR 102016016472-9

(51) Int. Cl. B60L 11/18; G01R 31/36; B60L 3/12; H01M 10/48; B60R 16/033; H01M 10/06

(52) U.S. Cl. CPC B60L 11/1861; G01R 31/3679; B60L 3/12; H01M 2220/20; H01M 10/486; B60R 16/033; H01M 10/06; G01R 31/3689

(57) ABSTRACT

It is herein described a battery monitoring system, in particular for a vehicle battery, which comprises the steps of: calculating, based on the battery voltage (1), the parameters of the battery state of health (SoH), battery state of charge (SoC) and stand-by current (IOD); comparing the battery state of health (SoH), the battery state of charge (SoC) and stand-by current (IOD) parameters with their previously established limits; and providing a warning sign when any parameter is different from its previously pre-defined limit. The system allows monitoring a vehicle battery (1) beginning from its installation and provides the driver indications about the necessity of maintenance or replacement thereof, exclusively based on the battery voltage, measured at specific times of the vehicle operation.

The present invention relates to a system and a method for monitoring vehicles battery and more particularly relates to a monitoring system which calculates parameters of vehicle batteries, particularly those of lead-acid, such as: state of health, state of charge and standby current.

More particularly, the present invention relates to a battery parameters monitoring system, only based on the battery voltage obtained at specific times and conditions of the battery, as well as to be able to provide the driver a warning sign regarding to a degradation condition, imminent failure or improper use of the battery, likely to harm the vehicle systems.

### STATE OF THE ART

The automotive battery has essential functions for the vehicle operation, such as:
when the engine is running, to stabilize the alternator voltage acting as a filter absorbing voltage fluctuations, since this can cause damages to the vehicle electronic system;
alternator power complementation when the alternator generation capacity is less than that required and when the electrical balance is negative;
supplying power to the start engine and ignition system for internal combustion engine (ICE) starting; and
when the ICE is off, to feed the vehicle electrical charges that have standby current (IOD).

The natural wear of a battery impairs its charging capacity and thus its functionality. Therefore, it is imperative to monitor the battery state of health in order to avoid surprises for the driver. This situation is particularly critical in vehicles with cold starting systems (alcohol or flex engines), in which, before the ICE starting, the battery should provide enough power for the fuel primary heating.

The ignition off draw IOD is a risk to the battery, because, if high, it can draw battery power making it unable to start the ICE. Thus, there is a need to monitor this parameter, so as to avoid troubles to the driver due to battery discharge.

Specific electronic components, named intelligent battery sensor (IBS), are already used by the global automotive industry in order to calculate the IOD, through specific current sensor, and evaluate the state of charge and state of health of the battery. The market and patent databases have some systems that measure these battery parameters such as state of charge: U.S. Pat. No. 7,423,408 and U.S. Pat. No. 8,386,199; state of health: U.S. Pat. No. 7,741,849; and the voltage sag in the engine starting: U.S. Pat. No. 8,386,199. However, in the searches carried out were not found documents relating to the determination of standby current or battery capacity without using sensors and specific modules. The voltage sag can be defined as the difference, in volts, between the nominal battery voltage and the minimum battery voltage (voltage sag) occurring during ICE starting. Notwithstanding, documents have not been found, in the art, that link the battery voltage sag with the vehicle operating parameters, so as to provide an accurate indication of it feasibility of use on a specific vehicle.

Said sensors are responsible for verifying and informing all battery diagnosis, a mandatory requirement for systems such as, for example, the start&stop system, which uses this information to turn off the vehicle ICE. In this system, the control module receives several battery parameters, through the IBS, to ensure that it will be able to actuate the start engine again to turn on the ICE, promoting safety and reliability to the system. This optimizes the vehicle performance in terms of environmental issues, providing reduced fuel consumption and consequently reducing the emissions level.

Considering the importance of battery diagnosis, especially in vehicles that have a complex electronic architecture and require greater reliability of the battery, the IBS becomes a mandatory component. Despite its importance, IBS adds a high cost to the vehicle besides introducing another component, potentially able of failure. Furthermore, the intelligent battery sensor (IBS) is also used, as already mentioned, in Stop&Start systems, which increases the cost of the vehicle, due to its complexity, and requires additional sensors and redundancy logics to ensure the reliability and safety of the system.

The vehicles currently sold in Brazil and in other countries are provided with various electronic units, which may or may not be grouped into a single component. These units are related to vehicle features, such as windows control, doors opening devices, lighting controls, ICE integrated control, among others.

### OBJECTS OF THE INVENTION

It is a first object of the present invention a system for monitoring state of health, storage and operation of the battery installed in a vehicle, in a simple and practical way and especially without using the expensive Intelligent Battery Sensors (IBS).

It is another object of the invention an active battery monitoring system exclusively from voltage measurements supplied by the battery.

### SUMMARY OF THE INVENTION

It has surprisingly been found, and constitutes the object of the present invention, that the battery state of health, the battery state of charge and the standby current can all be monitored exclusively from battery voltage measurements, said measurements being performed at specific times and using particular methodologies.

Therefore, the present invention comprises a battery monitoring system, particularly for an automotive battery, said system comprising a voltage meter connected to the battery terminals and at least one electronic control unit able to perform the steps of: A) calculating, from the battery voltage, the battery state of health (SoH), the battery state of charge (SoC) and standby current (IOD) from the battery voltage; B) comparing the calculated parameters of SoH, SoC and IOD with their previously defined limits; and C) providing a warning sign when any one of the parameters are different from its respective predetermined limit. More particularly, the step A) comprises said electronic control unit A1) informing to said voltage meter the specific times of capturing said battery voltage; A2) receiving the voltage values captured from the battery; and A3) calculating the values for the SoH, the SoC or the IOD from the respective formulas.

More in particular, said electronic control unit processor is, thus, able to: detect the driver's intention of turning on the engine and activate the voltage meter; detect the vehicle turned off and start the timer, so that said timer may be able to process time measuring; receive the digital values concerning to the voltage values, at the battery terminals, captured by the voltage meter; calculate the battery state of health values (SoH), the battery state of charge (SoC) and the standby current (IOD) using the equations, tables, parameters and reading stored in the memory; compare the calculated parameters of SoH, SoC and IOD with respective limits stored in memory; and record and/or send a warning sign by means of I/O, in the event any parameter is different from a respective predetermined and stored in the memory limit.

Complementarily, said electronic control unit memory is also able to: store the limit values permanently; store the voltage values of readings performed by the voltage meter temporarily; store the formulas calculation parameters for determining the SoH, the SoC and IOD, permanently; and store the times permanently.

The present invention further comprises specific calculation methods for the SoH, SoC and IOD parameters, as per defined in the respective independent claims, and according to the details described in the respective dependent claims.

The proposed monitoring system is provided to diagnose battery vital parameters, adding also this function to an electronic control unit. To achieve this object, it is important that the proposed system accurately report the state of the battery.

As a result, the system of the present invention has the objective and is able to diagnose data such as battery state of charge, battery state of health, and calculate the IOD, which depends on the battery interaction with the vehicle electrical loads that operate in standby. The information provided by the system allows several opportunities for connectivity with the vehicle electronic system, so that the driver can, for example, be alerted to seek technical assistance for preventive maintenance if there is high IOD, thus avoiding the battery discharge. Another interaction would be to send a battery replacement warning sign, if it is almost failing by impairment of its vital functions.

### DESCRIPTION OF THE DRAWINGS

The object of the present invention will be better understood from the following detailed description, which is made by way of illustration and not limitation of the invention, which is supported by the illustrative accompanying drawings, in which:

FIG. 1 is a schematic diagram illustrating the battery voltage measuring circuit and the vehicle electronic control unit;

FIG. 2 is a flowchart illustrating the steps of the IOD calculation algorithm;

FIG. 3 is a voltage graph, in function of time, illustrating the minimum voltage of ICE starting;

FIG. 4 is a graph illustrating the battery state of charge from the resting voltage;

FIGS. 5A, 5B and 5C are graphs illustrating the IOD, as a function of time, for three specific conditions of the battery state of charge and the battery temperature;

FIG. 6 is a graph illustrating the relationship between the battery state of health with a minimum voltage and temperature; and

FIG. 7 is a graph illustrating the resting tension as a function of time.

### DESCRIPTION OF A PREFERRED EMBODIMENT OF THE INVENTION

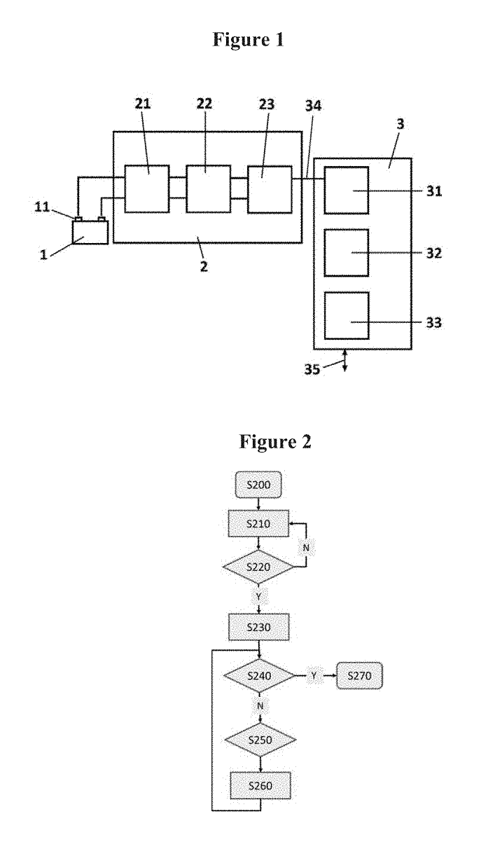

According to the basic principle of the present invention, it is possible to keep an efficient control on the vehicle battery condition without using specific sensors, which have high cost and are known as IBS. Therefore, the present invention uses only a voltage measuring circuit (2), which, electrically coupled between the battery (1) and the electronic control unit (3), as illustrated in FIG. 1, allows said control unit (3) to be able to, constantly, evaluate the battery condition (1).

Therefore, said voltage meter (2) comprises a filter (21) receiving the voltage supplied by the battery (1), directly from the battery poles (11). Said filter (21) is connected to a voltage divider (22), intended to reduce proportionally the battery voltage (1), and is connected, at the output, to an A/D converter (23), which transforms the voltage proportional analog value to a digital signal. In an alternative embodiment of the present invention, said voltage meter (2), which comprises filter (21), voltage divider (22) and A/D converter, (23) is integral part of the electronic control unit (3).

Said digital signal generated, at the output, by the voltage meter is fed into a respective digital input of an electronic control unit (3) line (34) embedded into the vehicle (not shown). More particularly, said electronic control unit (3) comprises, among others, at least one processor (31), at least one memory (32) and at least one timer (33), in addition to the usual I/O connections (35). With regard to said I/O connections (35) of the electronic control unit (3), and according to the vehicle automation level, the connections may be discrete or individualized (exclusive connections for sensors, actuators, etc.); or it may be provided a connection with the vehicle CAN or Ethernet network, whereby travels all data from the various vehicle sensors, as well as the control signals to the various individual actuators existing in the vehicle. Thus, and in accordance with the vehicle infrastructure, the digital signal supplied by the voltage meter (2) can be directly fed into the electronic control unit (3) from a digital input (34) or from the I/O connection (35) of the electronic control unit (3) with the vehicle CAN/Ethernet network (not shown).

Thus, the digital signal supplied by the voltage meter (2) is received by the electronic control unit (3), which processes it according to the methodological procedures previously defined. In particular, said electronic control unit (3) uses its memory (32) for storing the parameters and variables read or previously fed, so as to perform the analysis routines, which will be described in detail below.

Further, and alternatively, the system of the present invention can be implemented in a vehicle not provided with an electronic control unit. In this case, the methodological steps of analyzing the battery condition can be processed by one or more electronic circuits not equipped with processors or the like, but only comprising discrete electronic components.

In order to determine the battery state of charge, the battery state of health and the IOD, some concepts were developed and subsequently validated in vehicle and laboratory. The concepts of the parameters provided by the proposed system will be described below.

### State of Health—SoH

The battery state of health is an indication of the battery ageing and degradation that represents, in percentage, the capacity of a battery in relation to its nominal condition. Thus, the battery state of health directly influences the amount of energy that can be stored by the battery, supplied from the alternator and then provided it to the vehicle electro-electronic systems.

The developed system takes into account changes in the properties of the lead-acid battery throughout its useful life. Irreversible reactions and degradation are attributed to ageing and corrosion of internal components, loss of water by gasification, and loss of active material due to cycling. Furthermore, the batteries may have acid and sulfation stratification, which also degrade the battery state of health.

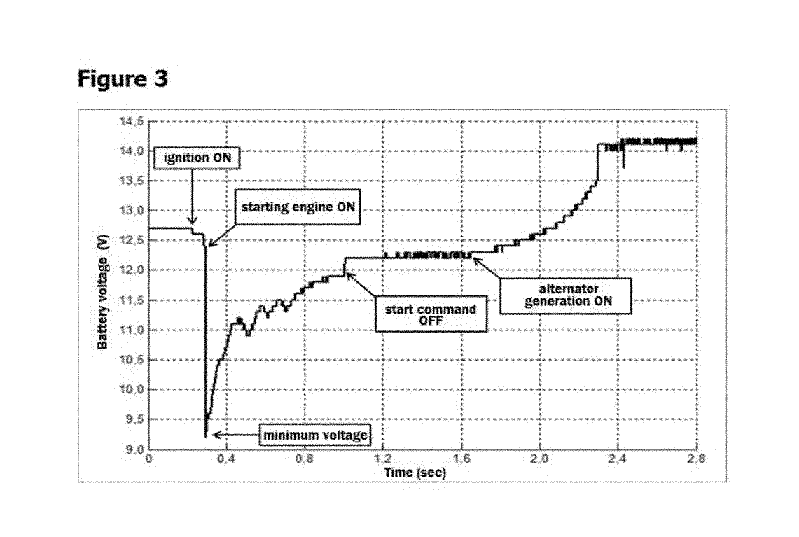

The developed method takes into account the battery voltage during the ICE starting, wherein the minimum voltage found during the starting (voltage sag) will be proportional to the battery state of health, according to FIG. 3.

The produced voltage sag is due to the abrupt increase in current density, promoting migration of sulfate ions (SO4-2) of sulfuric acid solution towards the plates. Once drained, the electrolyte can not spread quickly to keep the battery voltage. Due to the instantaneous nature of the discharge, only a limited amount of SO4-2 is transformed into PbSO4. After this intense and instantaneous discharge phase, the electrolyte is restored and the voltage returns to the previous level. In other words, the chemical reactions speed in the battery is not sufficient to supply the current demanded during the engine starting, what is the reason of a reduction in the battery (1) terminals (11) voltage, said reduction known as “voltage sag”.

When subjected to a profile discharge P (t), which depends on a timing t and has a duration t1, the battery voltage exhibits a minimum value Vmin. The lowest acceptable voltage, during discharging V1 for a specific application, and the lowest voltage Vnew of a new battery are used to define the battery state of health:

State of health SoH=(Vₘᵢₙ−V1)/(V_{new}−V1) (Equation 1) in which:
SoH is the battery state of health calculated based on the battery voltage during starting;
Vₘᵢₙ is the battery lowest acceptable voltage during ICE starting based on the vehicle configuration;
V_{new} is the lowest voltage of a new battery; and
V1 is the battery voltage measured during ICE starting.

More specifically, the value obtained for the battery state of health, calculated based on the battery voltage during an ICE starting operation is a number between 0 and 1, and the results closer to 1 show a battery with better state of health.

The parameter V1, also known as battery voltage sag, is related to a battery used in the vehicle provided with the system, according to the present invention. Said parameter shows, as stated, the lowest voltage measured at the battery terminals during the ICE starting operation. On the other hand, Vnew has the same concept, but the lowest voltage measured in a new battery. In particular, the voltage sag value of a new battery is a parameter previously informed to the system.

Finally, the lowest acceptable voltage (Vmin) during V1 discharge (i.e., the ICE starting) is used as restrictive limit to ensure proper operation of the vehicle electronic modules, since the micro controllers, that control such modules, have a restricted supply voltage range to allow thereof to stay connected.

Similarly, in a Start&Stop vehicle, the battery state of health parameter will be more restrictive compared to a conventional vehicle (no start&stop), since in this system a battery is most required, suffering constant charge and discharge cycles, which will hasten the degradation of the battery state of health.

Thus, the proposed system has the purpose of diagnosing the battery state of health according to the voltage. Therefore, as soon as is detected the driver's intention to turn on the ICE, for example, upon detection of the ignition key movement to the position of “key-on”, the electronic control unit (3) activates the voltage meter (2) via line (34), so as to receive the signals from the voltage meter (2) related to the voltages measured in the battery (1). In order to obtain the voltage sag (V1) during the ICE starting, it is only necessary that the electronic control unit (3) compares the reported voltage values and selects the lowest value measured by the voltage meter (2).

Once detected the voltage sag (V1) value during the ICE starting, the electronic control unit (3) retrieves the values (Vmin) and (Vnew), previously stored in memory (32), then calculating the battery (1) state of health (SoH) value, using the equation 1 (also previously stored in the memory 32). Finally, the calculated SoH value is compared with a value (SohL) also previously stored in the memory (32). Thus, if the calculated SoH value is less than the limit value (SohL), the system considers that the vehicle battery (1) is no longer in perfect working conditions, alert the driver of this fact. Such warning sign can be done through a failure indication on the vehicle dashboard (not shown). Anyway, necessarily, said failure indication generates a log in the memory (32), which can be recovered from the OBDII connection.

In other words, the battery monitoring method, in particular to calculate the state of health (SoH) of a battery (1) installed in a vehicle, from the voltage sag (V1), comprises the steps of: identifying the intention of starting (key-on) the vehicle internal combustion engine; measuring the battery (1) voltage during the engine starting; and identifying the voltage sag (V1). Furthermore, said method further comprises the steps of:

SH1) calculating the battery state of health (SoH), based on the voltage sag (V1) and vehicle configuration (Vmin) using the formula:

SoH=(Vmin−V1)/(Vnew−V1) (Equation 1)

wherein: SoH is the battery state of health calculated based on the battery voltage during the starting function; Vmin is the battery lowest acceptable voltage during the ICE starting based on vehicle configuration; Vnew is the voltage sag of a new battery; and V1 is the battery voltage sag measured during the ICE starting;
SH2) comparing the calculated value of the battery (1) state of health (SoH) with a limit value (SohL); and
SH3) registering and/or sending a warning failure sign if the SoH value is less than the limit SohL.

### State of Charge (SoC)

The state of charge is the remaining amount of charge in the battery, represented as a percentage of the rated charge.

The battery state of charge SoC determination can be a problem with more or less complexity depending on the battery type and the application in which it is used.

The following equation shows the battery state of charge concept:

State of charge(SoC)=(current amount of charge)/(total amount of charge) (Equation 3)

In which:
current amount of charge is a parameter calculated from the battery resting voltage measurement, said measurement taken after a contact time TR1 from ICE turned off; and
total amount of charge corresponds to the battery full charge in a new condition, i.e., corresponding to its rated load.

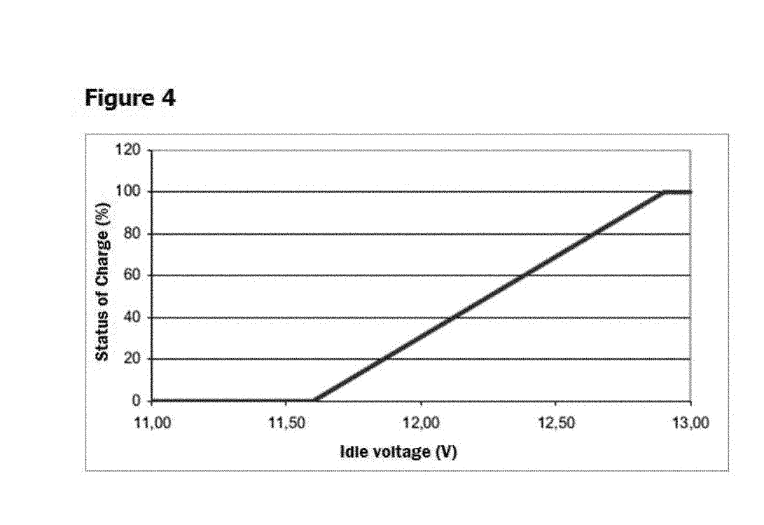

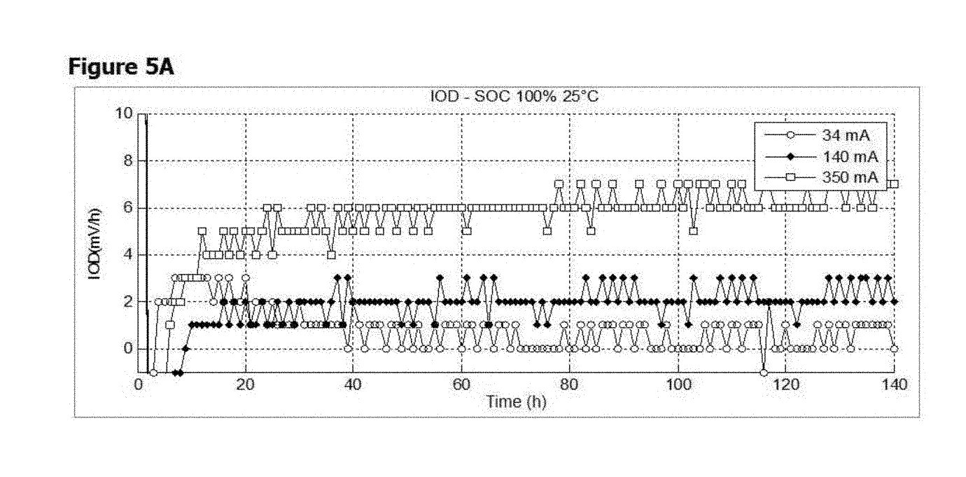

In a lead-acid battery, there is a known dependency between the resting voltage and its respective state of charge, as may be seen in FIG. 4. It is understood as resting voltage, the battery voltage measured after a resting time, after the engine turned off (key-off), enough to remove the influences of recharges or discharges, to which the battery has been subjected to.

The proposed system uses the resting voltage feature, which is the battery state of charge with good correlation after the battery resting period. In the performed tests, it was found that the battery minimum resting period (TR1) is about 4 hours after key-off. Thus, as soon is detected the ICE turned off, the timer (33) starts counting the time elapsed until it reaches to the value (TR1), pre-set and stored in the electronic control unit (3) memory (32). At this time, the voltage meter (2) captures the battery resting voltage (VR1), converting it into a digital value, which is fed into the electronic control unit (3).

After the value (VR1) is received by the electronic control unit (3), it calculates the battery (1) state of charge (SoC) from the correlation between resting voltage and state of charge, as illustrated in FIG. 4. Therefore, the electronic control unit (3) memory (32) is previously supplied with the curve features defined in the graph of FIG. 4, which is, as mentioned, performed in laboratory using a new battery having similar characteristics to the vehicle battery (1). Furthermore, said curve can be fed into the memory (32) either as a function or a functions group or also as a table. In a preferred embodiment of the invention, the curve representing the correlation between resting voltage and state of charge (FIG. 4) is stored as a table, a solution which saves processing.

Finally, the measurement of the SoC is compared with a limit value (SOCL), also previously stored in memory (32). Thus, if the calculated SoC value is less than the limit value (SoCL), the system considers that the vehicle battery (1) is no longer in perfect working order, alerting the driver of this failure. Such warning sign can be similarly provided by an error indication on the vehicle dashboard (not shown), as well as, necessarily it generates a log in the memory (32), which can be retrieved from the OBDII connection.

In other words, according to the present invention, the battery monitoring method, in particular for calculating the state of charge (SoC) of a battery (1) installed in a vehicle, comprises the steps of:

SC1) identifying the engine (ICE) turned off (key-off));
SC2) counting and waiting a resting time (TR1) after the ICE turned off;
SC3) measuring the voltage (VR1) at the battery (1) poles (11);
SC4) calculating the battery state of charge (SoC), using the formula:

SoC=(current amount of charge)/(total amount of charge) (Equation 3)

wherein: the current amount of charge is a parameter calculated from the measurement of the battery resting voltage (VR1); and the total amount of charge corresponds to the battery full charge in a new condition, that is, corresponding to its rated load;

SC5) comparing the calculated state of charge (SoC) of the battery with a state of charge limit value (SoCl); and
SC6) registering and/or sending a warning failure sign, if the SoC value is less than the state of charge limit value SoCl.

Furthermore, said correlation between resting voltage (VR1) and current amount of charge is established testing a new battery. Said correlation, as exemplarily illustrated in FIG. 4, can be used as a values correlation formula, or possibly from tabulated values entered into the memory (32).

According to the performed tests, it was possible to define that said resting time (TR1) should be about 4 hours, preferably with a variation of approximately 1 hour.

### Standby Current (IOD)

Although a battery deep discharge does not cause immediate degradation, even in cases of 100% discharge, a lead-acid battery can hold up to 200 cycles of charge and discharge; however, this kind of behavior is not acceptable for a commercial application in the automotive industry, especially in regard to the reliability of batteries and systems that it supports.

Consequently, it is all-important that the battery monitoring system is accurate and reliable for a vehicle. The IOD is a critical factor that is not fully under control of the battery manufacturer or the automotive industry, because the user can install electronic equipment after purchasing the vehicle, an aspect that undermines the original battery specification.

For a better understanding, it is important to point out that the ideal state of resting voltage is never reached when the battery is connected to the vehicle electronic system, due to the quiescent currents of the electronic modules, which discharge the battery continuously. Thus, even with ICE turned off and ignition off draw, there is a reduced electric current that discharges the battery.

The methodology for determining the IOD analyzes the time that the vehicle remained turn off (key-off) in order to eliminate any battery charge or discharge influence. When the resting time (TR2) is reached, the system starts a voltage evaluation over time. Here is used the parameter mV/h (millivolts per hour), which is the battery voltage drop measured at predetermined time intervals, for example 1 hour.

The equation to calculate this parameter is the following:

IOD=(VIODf−VIODi)/(TIODf−TIODi) (equation 4)

wherein:
IOD is the current drawn from the battery when the ignition is off
VIODi is the battery voltage measured after the resting period
VIODf is the battery voltage measured before actuating the vehicle network
TIODi is the initial time after finishing the resting period, and
TIODf is the final time after finishing the resting period.

The flowchart of FIG. 2 illustrates various steps of the methodology proposed by the system of the present invention, in order to obtain the variables of the above defined equation.

The FIG. 2 shows the following steps:

S200—start
S210—Engine off and key-off
S220—TR2 hours elapsed after last “key off” ?
S230—V|OD|=VBAT; T|OD|=Time (samples per hour)
S240—Network connected?
S250—After “x” minutes?

### S260—F=V|OD|=Vbat; T|OD|=Time

### S270—End

Accordingly, it is established the theoretical basis to prove the correspondence between the battery (1) consumed current during ignition off draw and the voltage drop during the time the vehicle remains with the ignition off draw.

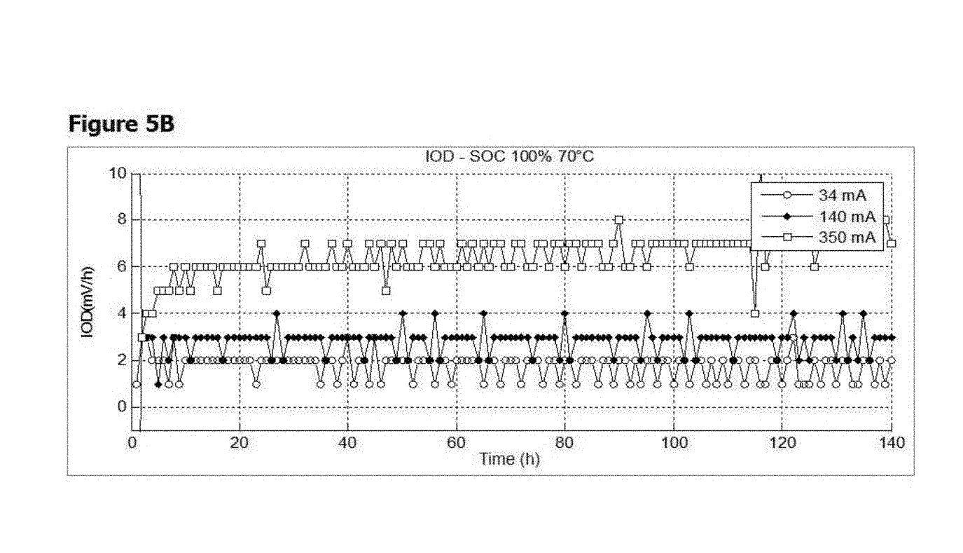

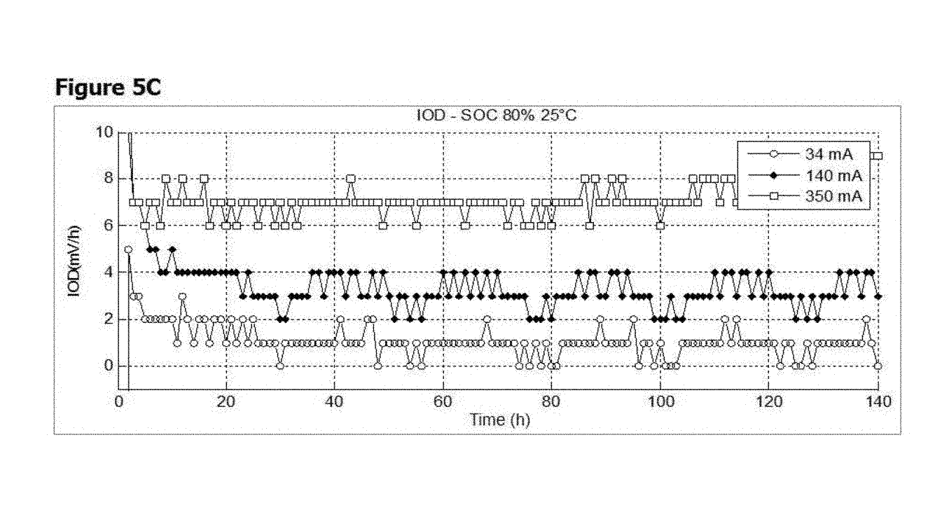

The proposed monitoring system uses this calculation to determine the quiescent current of the battery electrical system that can discharge the battery. As can be seen in FIGS. 5A, 5B and 5C, there is a random behavior during the early hours of this measurement. As a result and in accordance with the analyzes performed of the system tests of the present invention, it was established that the system must wait at least 10 hours (TR2) to use the parameters obtained from the equation 4 in order to diagnose the vehicle's electrical system and to determine the IOD magnitude.

Operationally, once detected the ICE turned off, the timer (33) starts counting the time elapsed until it reaches the value (TR2) pre-set and stored in memory (32) of the electronic control unit (3). At this time, the voltage meter (2) captures the battery resting voltage (VR2), converting it into a digital value, which is fed into the electronic control unit (3). Simultaneously, the timer (33) start to count the next time interval so as the next reading of the battery (1) resting voltage (VR2) shall be made.

Once all values (VR2) are received by the electronic control unit (3), such values properly stored in memory (32), said electronic control unit (3) calculates the battery (1) standby current (IOD) through the correlation between the measured resting voltages (VIODi and VIODf variables) and the elapsed time between first and last voltage reading (TIODi and TIODf variables), i.e. the time the vehicle has remained quiescent (off) as illustrated in the above equation 4.

Finally, the IOD calculated value is compared with a limit value (IODL), also previously stored in the memory (32). Thus, if the calculated value for the IOD is greater than the limit value (IODL), the system considers that the vehicle battery (1) is being subjecting to an excessive current drain, alerting the driver of this failure. Said warning sign can be similarly done by means of a failure indication on the vehicle dashboard (not shown), as well as, necessarily, generates a log in the memory (32), which can be retrieved from the OBDII connection.

In other words, the method of monitoring battery of the invention, in particular for the calculation of ignition off draw (IOD) of a battery (1) installed in a vehicle, comprises the steps of:

SI1) identifying the engine (ICE) turned off (key-off));
SI2) counting and waiting a resting time (TR2) after the ICE turned off;
SI3) measuring the voltage (VR2) at the battery (1) poles (11);
SI4) calculating the battery ignition off draw (IOD), using the formula:

IOD=(VIODf−VIODi)/(TIODf−TIODi) (Equation 4)

wherein: IOD is the current drawn from the battery when the ignition is off (Key-off); VIODi is the battery voltage measured after the resting time (TR2); VIODf is the battery voltage measured before activating the vehicle network; TIODi is the initial time after finishing the resting period; and TIODf is the final time after finishing the resting period;
SI5) comparing the battery calculated ignition off draw (IOD) with an ignition off draw limit value (IODL); and
SI6) registering and/or sending a warning failure sign if the IOD value is greater than the IODL value.

More particularly, the battery voltage (VIODf), measured before actuating the vehicle network (key-on), is obtained by voltage timed samplings at the battery poles. In addition, in order to avoid unnecessary accumulation of data in the memory, are disregarded the captured voltage reading (VIODf) in a respective time (TIODf), the previously sampled value and the respective sampling time.

Said timed samplings of the battery voltage, performed in one-hour periods, ensure reliable results, as determined in preliminary tests. Finally, also as observed from the tests, the resting time (TR2) should be about 10 hours, preferably with a two-hour margin. Such resting time ensures that the voltage values will be collected with the battery (1) free of interference.

### Experiment Results

### Determination of the Battery State of Health SoH Based on the Voltage Sag During the ICE Starting

The strategy validation of capturing minimum voltage, in order to estimate the battery state of health, was obtained by means of experiments in a controlled fleet of vehicles. Said vehicles (cars) were prepared for continuous acquisition of battery voltage during periods ranging from weeks to months depending on the vehicle. It is worth mentioned that the monitored vehicles had different use profiles, ensuring significance in working conditions of the batteries.

In addition to recording the battery voltage continuously, the acquisition of battery voltage has allowed the registration of the key-on, starting early, starting late and key-off events. The engine water temperature was recorded together with the starting early event. The data acquisition rate was adjusted according to the operating system, being 1 Hz for key-off, 100 Hz for key-on and 500 Hz for the engine starting period.

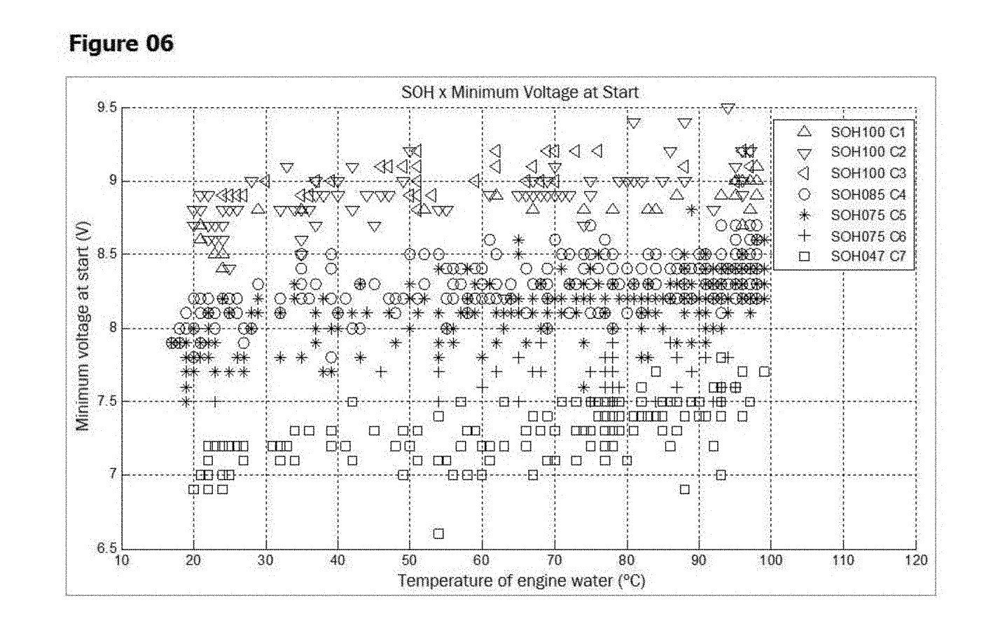

FIG. 6 shows the minimum voltages recording, obtained during the engine starting in vehicles equipped with the same state of charge and different states of health batteries, in order to observe the proposed methodology. Each starting voltage record is accompanied by the engine water temperature at the time of engine starting. The engine water temperature was measured expecting to obtain a temperature estimate where the battery is located as well as to evaluate the correlation between the minimum engine starting voltage and temperature at the time of engine starting.

The vehicles C1, C2, C3, equipped with a 100% battery state of health, presented the lowest voltage sags during the engine starting. Further down the graph, are shown the voltages in those vehicles equipped with 85% battery state of health (vehicle C4), 75% battery state of health (vehicles C5 and C6) and 47% battery state of health (vehicle C7), respectively. It is noted from the graph that, although the observed deviations, the minimum voltage during the engine starting is related to the battery ageing.

In addition, and in order to validate the parameter “voltage sag” measured during the ICE starting, the state of health (SoH) of each battery was calculated from usual parameters of the art, i.e. comparing the battery charging capacity in its current condition (battery used) as well as a new battery (newly produced).

Therefore, and as mentioned above, the minimum voltage in the engine starting is proportional to the battery state of health and also to its current charging capacity. The battery state of health and its current charging capacity are similar parameters representing the proportional degradation during the battery life.

Specifically, and from Cnew parameter, which is the reference capacity for a new battery, and Climit parameter, which is the minimum capacity acceptable for the application, it can be established the battery state of health, based on the load capacity, according to the art precepts, as follows:

State of health=(C_{current}−Cₗᵢₘᵢₜ)(Cnew−Cₗᵢₘᵢₜ) (Equation 2)

wherein:
Ccurrent is the battery capacity installed in the vehicle and evaluated by the proposed monitoring system;
Cnew is the charge capacity of a new battery; and
Climit is the minimum charge capacity acceptable by the vehicle.

Using the equations 1 and 2 for the conditions shown in the graph of FIG. 6, it is possible to obtain good correspondence between the battery state of health obtained in laboratory and the calculated value, observing the ideal and limiting conditions acceptable for the vehicle battery operation.

Analyzing each battery state of health condition individually (see FIG. 6), it is revealed that the voltage sag is greater at lower temperatures. This is because at high temperatures the ICE oil viscosity is smaller, thus making easy the engine starting by reducing its inertial torque. It can be seen, then, that the temperature is proportional to the voltage sag, but it does not show linear behavior.

### Determination of Battery State of Charge SoC by Resting Voltage

Using the same validation database of the battery state of health, it is also possible to determine the battery state of charge by correlation with the resting voltage. For the purpose, it is necessary to wait a specific period to remove charging and discharging influences.

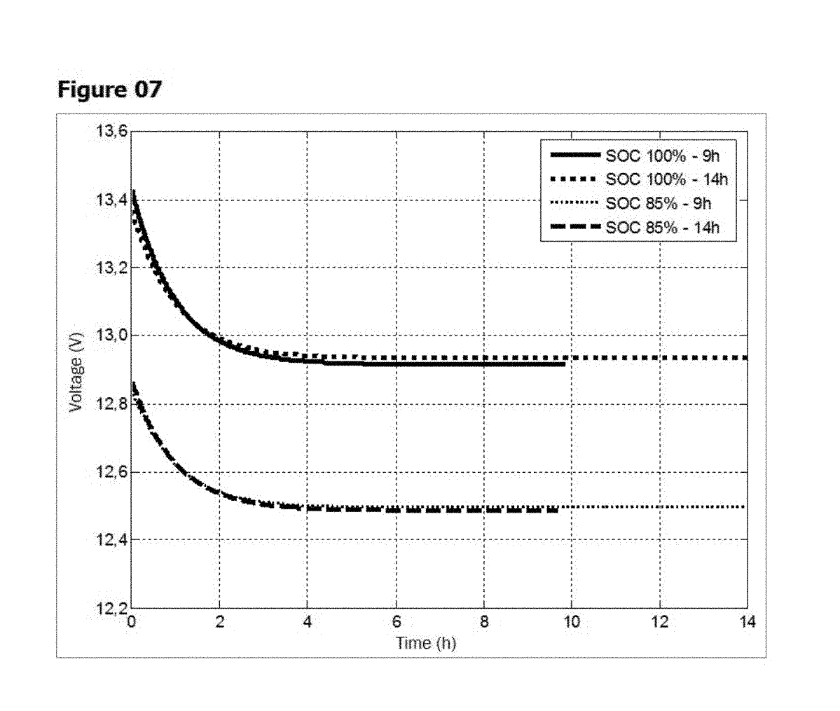

FIG. 7 shows the battery voltage curve after the ICE turned off. It is observed that after a specific period of inactivity, the voltage reaches a stable value, which is known as resting voltage. This voltage directly shows the battery state of charge.

The relationship between resting voltage and the battery state of charge depends on physicochemical aspects, i.e., it varies according to the capacity, chemicals elements used on plates and chemical composition used in the battery electrolyte

### Determination of IOD by Voltage Decay Rate

The IOD calculation was obtained by means of an experiment that submits the battery at different discharge currents, relating said discharge currents to their voltage drop. It were chosen the currents 34 mA, 140 mA and 350 mA, thus, representing an IOD values range usually found in electronic equipment installed in vehicles in the aftermarket.

Said current values were applied in three different operating conditions: 100% battery state of charge and 25° C., 100% battery state of charge and 70° C., and 80% battery state of charge, and 25° C. The voltage variation rates, under the three described conditions, are shown respectively in FIGS. 5A, 5B and 5C.

It is noted by the graphs that higher is the discharging current, the greater is the voltage drops in mV/h. However, it is clear that the relationship between these variables is not linear.

A comparison analysis between FIGS. 5A and 5B indicates that the voltage decay rate increases with temperature increasing. This phenomenon can be explained by the battery self-discharge, which also increases with temperature.

Analyzing FIGS. 5A and 5C, it can be seen that the IOD is inversely proportional to the battery state of charge, since the 80% battery state of charge showed higher IOD than the 100% battery state of charge.

### CONCLUSION

According to the experimental results, it was possible to prove the proposed methodological solution to calculate battery-related parameters by means of the voltage measured at specific times of the vehicle operation.

It has been found that the voltage sag in the ICE starting is associated with the battery state of health since the higher ageing batteries have showed higher voltage sag. It has also been proven that for the same battery state of health, higher voltage sags were observed at lower temperatures, but non-linearly.

The acquisition of voltage at the battery resting periods showed correspondence with the battery state of charge values, tabulated and widespread by the battery manufacturers. Nevertheless, said relationship is not exists if the battery is previously subjected to charging and discharging.

While the ignition is off draw, the voltage decay rate is directly related to the discharge current at which the battery is subjected. Such correlation is not linear, since if the current magnitude is increased ten times, the voltage decay rate, in mV/h, increases approximately three times. The correspondence between the voltage drop rate and the discharge current can be used to calculate the IOD of the vehicle.

The battery low cost diagnosis creates a new scenario for the driver interaction, so that he can receive preventive maintenance information of the component and prevent future failures in field.

Finally, it should be emphasized that the above mentioned tests confirm the viability of the system described in the present invention, i.e., it is possible to monitor the battery (1) state only using specific methodologies of capturing battery (1) voltage at specific times. Therefore, the solution herein proposed eliminates the need of expensive specific sensors (MS), which monitor the voltage and current of the battery (1), without an impairment of the obtained results.

1. A battery monitoring system, in particular for a vehicle battery (1), said system comprising a voltage meter (2) connected to battery terminals (11) and at least one electronic control unit (3), wherein the battery monitoring system comprises the steps of:
A) calculating, from the battery voltage, the battery state of health (SoH), the battery state of charge (SoC) and the standby current from the battery voltage;
B) comparing the calculated parameters of battery state of health (SoH), battery state of charge (SoC) and standby current with respective limits (SoH_{L}, SOC_{L}, Sb_{L}) previously defined; and
C) providing a warning sign when any of the parameters is different from the respective predetermined limit.

2. The system according to claim 1, wherein the step A) to calculate, from the battery voltage, the battery state of health (SoH), the battery state of charge (SoC) or the standby current from the battery voltage, comprises the electronic control unit (3) to:
A1) inform to the voltage meter (2) the specific times (key-on, T_{R1}, T_{R2}) of the battery (1) voltage capturing (V1; V_{R1}, V_{R2});
A2) receive the voltage values (V1, V_{R1}, V_{R2}) captured from the battery (1); and
A3) calculate values regarding to the battery state of health (SoH), the battery state of charge (SoC) or standby current from the respective formulas.

3. The system according to claim 1, wherein the electronic control unit (3) comprises at least one processor (31), at least one memory (32) and at least one timer (33), as well as a digital communicating line (34) with the timer (2), and a communication, control and signal reception I/O (35), to several electronic systems of the vehicle.

4. The system according to claim 3, wherein said electronic control unit (3) further comprises a voltage meter (2), said voltage meter comprising at least one filter (21), a voltage divider (22) and an A/D converter (23).

5. The system according to claim 1, wherein the processor (31) of the electronic control unit (3) is able to:
detect the driver's intention of turning engine on (key-on) and activate the voltage meter (2);
detect the vehicle turned off (key-off) and actuate the timer (33), so that the timer (33) can measure the times (T_{R1}, T_{R2});
receive the digital values, via line (34), concerning the voltage values (V₁; V_{R1}, V_{R2}) at the battery terminals (11), captured by the voltage meter (2);
calculate the values of the battery state of health (SoH), the battery state of charge (SoC) and the standby current using the equations, tables, and reading parameters stored in the memory (32);
compare the calculated parameters of the battery state of health (SoH), the battery state of charge (SoC) and the standby current with the respective limits (SoH_{L}, SOC_{L}, Sb_{L}) stored in memory (32); and
register and/or send a warning sign, via I/O (35), if any parameter is different from the respective predetermined limit and stored in the memory (32).

6. The system according to claim 1, wherein the electronic control unit (3) memory (32) is able to:
store the limit values (SoH_{L}, SOC_{L}, Sb_{L}) permanently;
store the voltage values (V₁, V_{R1}, V_{R2}) of the readings performed by the voltage meter (2), temporarily;
store the formulas calculation parameters (Equation 1, Equation 3, Equation 4) which determine the battery state of health (SoH), the battery state of charge (SoC) and the stand-by current, permanently; and
store the time values (T_{R1}, T_{R2}), permanently.

7. A battery monitoring method, in particular to calculate a state of health (SoH) of a battery (1) installed in a vehicle, from a voltage drop (V₁) comprising the steps of: identifying the intention of starting (key-on) a vehicle combustion engine; measuring the battery voltage (1) during the starting; and identifying the voltage drop (V₁) wherein said method further comprises the steps of:
SH1) calculating the battery state of health (SoH), based on the voltage drop (V₁) and vehicle configuration (Vₘᵢₙ) using the formula:
SoH=(Vₘᵢₙ−V₁)(V_{new}−V₁) (Equation 1)
in which: SoH is the battery state of health calculated based on the battery voltage during the starting function; V₁ is the battery lowest acceptable voltage during the ICE starting based on vehicle configuration; V_{new} is the voltage drop of a new battery; and Vₘᵢₙ is the battery voltage drop measured during the ICE starting;
SH2) comparing the calculated value of the battery (1) state of health (SoH) with a limit value (SoH_{L}); and
SH3) registering and/or sending a warning failure sign if the SoH value is less than the limit SoH_{L}.

8. A battery monitoring method, in particular to calculate the state of charge (SoC) of a battery (1) installed in a vehicle, wherein it comprises the steps of:
SC1) identifying the engine (ICE) turned off (key-off));
SC2) counting and waiting a resting time (T_{R1}) after the ICE turned off;
SC3) measuring the voltage (V_{R1}) at the battery terminals (11);
SC4) calculating the battery state of charge (SoC), using the formula:
SoC=(current amount of charge)/(total amount of charge)
in which: the current amount of charge is a parameter calculated from the measurement of the battery resting voltage (V_{R1}); and the total amount of charge corresponds to the battery full charge in a new condition, that is, corresponding to its rated load;
SC5) comparing the calculated state of charge (SoC) of the battery with a state of charge limit value (SoC_{L}); and
SC6) registering and/or sending a warning failure sign, if the SoC value is less than the state of charge limit value SoC_{L}.

9. The method according to claim 8, wherein the resting time (T_{R1}) is about 4 hours.

10. The method according to claim 8, wherein said correlation between the resting voltage (V_{R1}) and the amount of current charge is established by testing a new battery.

11. A battery monitoring method, in particular for calculating the standby current of a battery (1) installed in a vehicle, wherein it comprises the steps of:
SI1) identifying the engine (ICE) turned off (key-off));
SI2) counting and waiting a resting time (T_{R2}) after the ICE turned off;
SI3) measuring the voltage (V_{R2}) at the battery (1) terminals (11);
SI4) calculating the standby, using the formula:
Standby=(V_{Sbi}−V_{Sbf})/(T_{Sbf}−T_{Sbi})
in which: Standby is the current drawn from the battery when the ignition is off (Key-off); V_{Sbi} is the battery voltage measured after the resting time (T_{R2}); V_{Sbf} is the battery voltage measured before activating the vehicle network; T_{Sbi} is the initial time after finishing the resting period; and T_{Sbf} is the final time after finishing the resting period;
SI5) comparing the battery calculated standby with a limit value (Sb_{L}); and
SI6) registering and/or sending a warning failure sign if the standby value is greater than the Sb_{L} value.

12. The method according to claim 11, wherein the resting time (T_{R2}) is about 10 hours.

13. The method according to claim 11, wherein the battery voltage (V_{Sbf}) measured before actuating the vehicle network (key-on) is obtained by voltage timed samplings at the battery poles.

14. The method according to claim 13, wherein the battery voltage timed samplings are carried out in one hour periods.

15. The method according to claim 13, wherein, once captured a voltage reading (V_{Sbf}) in a respective time (T_{Sbf}), the previously sampled value and the respective sampling time are discarded.
